(19) United States
(12) Patent Application Publication
(10) Pub. No.: US 2018/0199454 A1
(43) Pub. Date: Jul. 12, 2018

(54) ELECTRONIC DEVICE

(71) Applicant: KYOCERA Corporation, Kyoto-shi (JP)

(72) Inventors: Tatsuya YANO, Yokohama-shi (JP); Yousuke NAKANISHI, Yokohama-shi (JP); Yugo ITO, Yamato-shi (JP)

(21) Appl. No.: 15/863,071

(22) Filed: Jan. 5, 2018

(30) Foreign Application Priority Data
Jan. 6, 2017 (JP) 2017-001367
Jan. 6, 2017 (JP) 2017-001368

(51) Int. Cl. H05K 5/02; H05K 5/03; H05K 5/00; H04B 1/3888

(52) U.S. Cl. CPC H05K 5/0217; H05K 5/0221; H05K 5/0226; H04M 1/026; H05K 5/0086; H04B 1/3888; H05K 5/03

(57) ABSTRACT

An electronic device includes a housing including a first casing and a second casing coupled to each other, and a bumper partially covering a side face of the housing. The bumper includes a first latch and a second latch that are protruding from a face facing the side face of the housing. The first latch is extending to an inside of the housing through a hole formed on the side face of the housing and engaged with a side wall of the housing from the inside of the housing. The second latch includes a through hole and is inserted into a groove formed on a side face of the first casing. The second latch is engaged with a protrusion that is protruding from a face of the second casing facing the first casing and inserted into the through hole.

### CROSS REFERENCE TO RELATED APPLICATIONS

This application claims priority from and the benefit of Japanese Patent Applications No. 2017-001367 and No. 2017-001368 filed on Jan. 6, 2017, the entire contents of which are incorporated herein by reference.

### TECHNICAL FIELD

The present disclosure relates to an electronic device.

### BACKGROUND

Electronic devices such as mobile phones are known.

### SUMMARY

An electronic device according to an embodiment of the disclosure includes a housing including a first casing and a second casing engaged with each other, and a bumper which partially covers a side face of the housing. The bumper includes a first latch and a second latch that protrude from a surface of the bumper which faces the side face of the housing. The first latch extends to an inner part of the housing through a hole formed on the side face of the housing and engaged with a side wall of the housing from inside of the housing. The second latch includes a through hole, is inserted into a groove formed on the side face of the first casing, and engages a protrusion that protrudes from a face of the second casing facing the first casing and inserted into the through hole.

An electronic device according to an embodiment of the disclosure is an electronic device including a first housing and a second housing which are openably and closably coupled to each other via a hinge. The electronic device includes at least one first bumper, at least one second bumper, and at least one third bumper. The at least one first bumper each at least partially covers a second end portion of the first housing opposite to a first end portion of the first housing connected to the second housing via the hinge. The at least one second bumper each at least partially covers a fourth end portion of the second housing opposite to a third end portion of the second housing connected to the first housing via the hinge. The at least one third bumper each at least partially covers the third end portion of the second housing.

### BRIEF DESCRIPTION OF THE DRAWINGS

In the accompanying drawings:

FIG. 1 is a diagram illustrating a perspective view of an electronic device in a closed state according to an embodiment of the present disclosure.

FIG. 2 is a diagram illustrating a perspective view of the electronic device in an open state viewed from a front side.

FIG. 3 is a diagram illustrating a perspective view of the electronic device in the closed state viewed from a rear side.

FIG. 4 is a diagram illustrating an enlarged view of the principal components in the vicinity of a window of a front case.

FIG. 5 is a diagram illustrating an exploded view of an upper housing.

FIGS. 6A to 6F are diagrams illustrating six views of a bumper.

FIGS. 7A and 7B are diagrams illustrating end portions of the front casing.

FIG. 8 is a diagram illustrating a state in which the bumper is temporarily fixed to the front casing.

### DETAILED DESCRIPTION

An electronic device is conventionally provided with a bumper for the purpose of reducing damages thereto such as when the electronic device is dropped. However, attaching the bumper to the electronic device may make the electronic device bulky. The present disclosure relates to an electronic device that is prevented from becoming bulky on account of the bumper. The electronic device according to an embodiment of the present disclosure is prevented from becoming bulky on account of the bumper. Hereinafter, an embodiment of the present disclosure will be described with reference to the accompanying drawings.

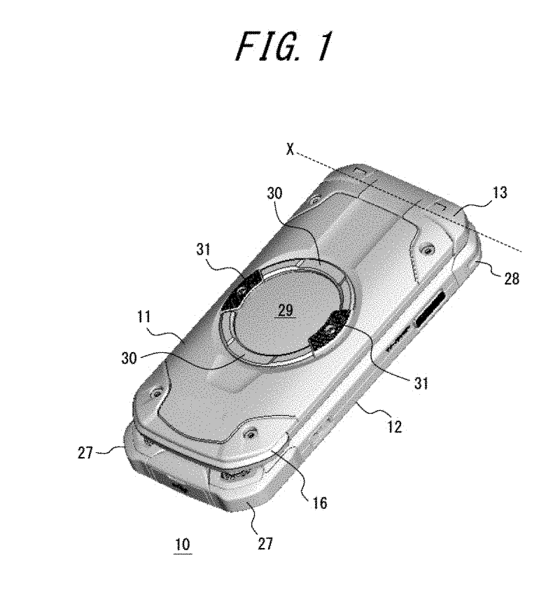

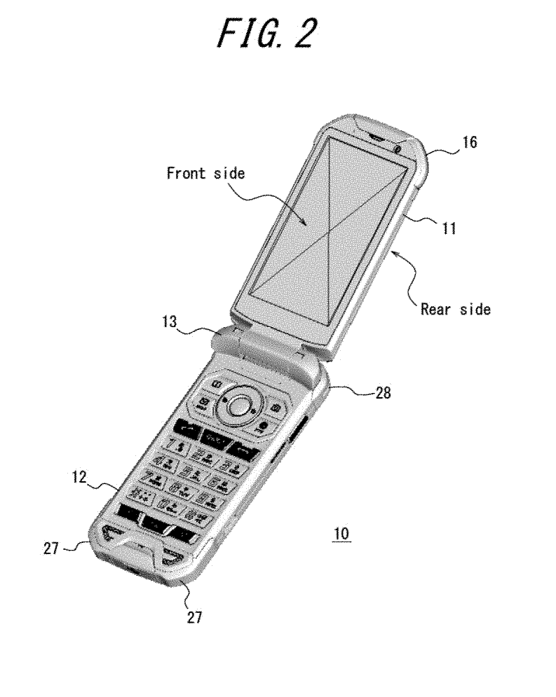

An electronic device 10 according to the embodiment of the present disclosure will be described with reference to FIG. 1 and FIG. 2.

The electronic device 10 is, for example, a flip phone, but may be any other device. As an overview, the electronic device 10 includes, for example, an upper housing 11 and a lower housing 12. The upper housing 11 and the lower housing 12 are openably and closably coupled to each other via a hinge 13. The hinge 13 may include, for example, a first hinge support provided at an end portion of the upper housing 11 facing the lower housing 12, a second hinge support provided at an end portion of the lower housing 12 facing the upper housing 11, and a tilt hinge supported by the first hinge support and the second hinge support. The upper housing 11 may include, for example, a display and a receiver. The lower housing 12 may include, for example, physical keys and a microphone. A state in which the upper housing 11 and the lower housing 12 meet each other, as illustrated in FIG. 1, is referred to as a closed state. In the closed state, an angle formed between the upper housing 11 and the lower housing 12 is, for example, approximately 0 degrees. A state in which the upper housing 11 and the lower housing 12 are separate from each other, as illustrated in FIG. 2. is referred to as an open state. In the open state, the angle formed between the upper housing 11 and the lower housing 12 is, for example, less than 180 degrees. An inner side between the upper housing 11 and the lower housing 12 in the closed state is also referred to as a front side. An outer side of the upper housing 11 and the lower housing 12 in the closed state is also referred to as a rear side. As an overview, the upper housing 11 and the lower housing 12 may each be a hexahedron with a front face, a rear face, and four side faces.

The electronic device 10 includes any appropriate bumper. The bumper may be made of, for example, an elastomer. The bumper improves, for example, durability of the electronic device 10.

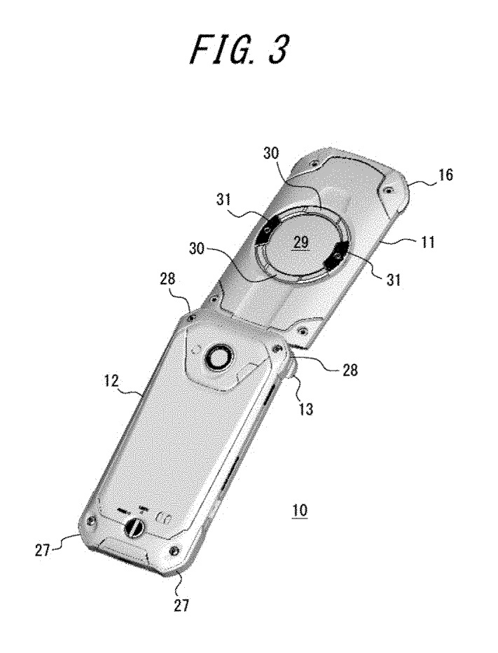

In particular, the electronic device 10 is provided with the bumper at portions thereof that are likely to hit the ground first when the electronic device 10 is dropped in the open state. Such portions that are likely to hit the ground first include, for example, two corners of an end portion of the upper housing 11 on a side facing away from the lower housing 12, two corners of an end portion of the lower housing 12 on a side facing away from the upper housing 11, and two corners of an end portion of the lower housing 12 on a side facing the upper housing 11. As illustrated in FIG. 3 by way of example, the electronic device 10 includes one first bumper 16 which covers the two corners of the end portion of the upper housing 11 on the side facing away from the lower housing 12. The electronic device 10 includes two second bumpers 27 which cover the two corners of the end portion of the lower housing 12 on the side facing away from the upper housing 11. The electronic device 10 includes two third bumpers 28 which cover two corners of the end portion of the lower housing 12 on the side facing the upper housing 11.

As illustrated in FIG. 1 by way of example, when the electronic device 10 is in the closed state, at least one third bumper 28 may each protrude from the upper housing 11 in a direction of a rotational axis X of the tilt hinge. This configuration reduces damages to the end portion of the upper housing 11 on a side facing the lower housing 12 when, for example, the electronic device 10 is dropped in the closed state. Therefore, even without a bumper attached to the end portion of the upper housing 11 on the side facing the lower housing 12, damage to this end portion may be reduced.

In the electronic device 10, the upper housing 11 includes a window 29, at least one bezel 30, and at least one fourth bumper 31 on the rear face of the upper housing 11. In an example illustrated in FIG. 1, two bezels 30 and two fourth bumpers 31 are provided.

The window 29 may be formed with, for example, a transmission member that transmits light in a predetermined wavelength band. Through the window 29, a user may view, for example, a screen on a sub-display provided on internally of the upper housing 11.

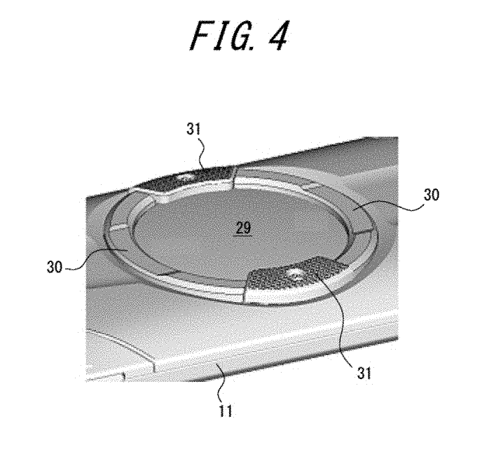

The at least one bezel 30 may each be a component independent of the upper housing 11, or integrally formed with the rear face of the upper housing 11. The at least one bezel 30 partially surrounds the window 29. As illustrated in FIG. 4, the at least one bezel 30 may each protrude from the rear face of the upper housing 11 further than the window 29.

The at least one fourth bumper 31 each partially surrounds the window 29. The at least one fourth bumper 31 may each be arranged at equal intervals in a circumferential direction of the window 29. The at least one fourth bumper 31 may each be fixed to the upper housing 11 via, for example, an adhesive member or a fastening member. The adhesive member may include, for example, an adhesive or a double-sided tape. The fastening member may include, for example, a screw. As illustrated in FIG. 4, the at least one fourth bumper 31 may each protrude from the rear face of the upper housing 11 further than the window 29 and the at least one bezel 30.

The fourth bumper 31 reduces damage to the window 29 and the at least one bezel 30 when, for example, the electronic device 10 is dropped. When the fourth bumper 31 provided independently of the upper housing 11 is damaged, a repair person may simply replace the fourth bumper 31. The upper housing 11 does not need to be disassembled, thereby reducing repair work.

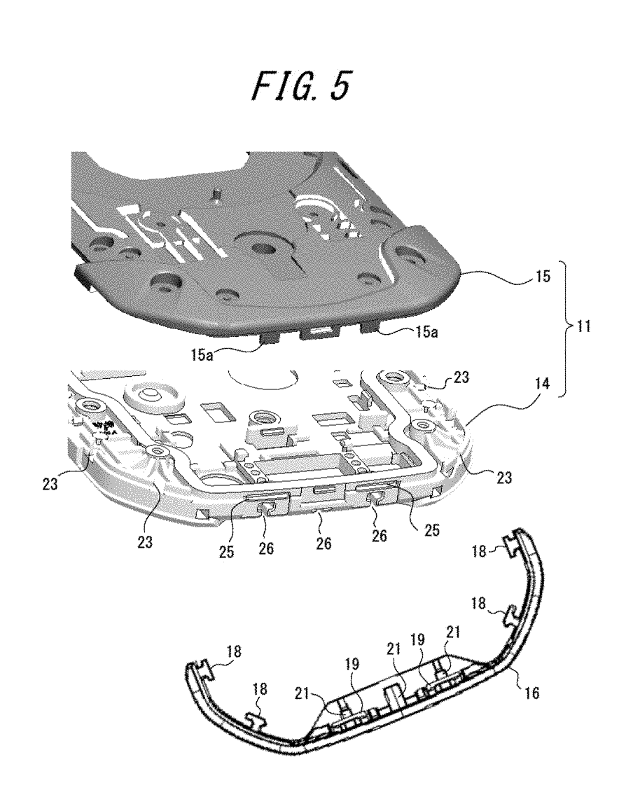

The upper housing 11 will be described in detail with reference to FIG. 5. FIG. 5 illustrates an end portion of the upper housing 11 opposite to the hinge 13. FIG. 5 omits electronic components such as a substrate provided inside the upper housing 11, and a display. As illustrated in FIG. 5, the upper housing 11 includes a front casing 14 and a rear casing 15. The front casing 14 is positioned on the front side of the upper housing 11. The rear casing 15 is positioned on the rear side of the upper housing 11. The first bumper 16 is attached to the upper housing 11. The front casing 14 and the rear casing 15 may be made of, for example, glass-containing resin.

In assembly of the upper housing 11, the first bumper 16 is temporarily fixed to the front casing 14, for example. The temporary attachment of the first bumper 16 will be described in detail later. After the temporary attachment of the first bumper 16, the rear casing 15 is engaged with the front casing 14. The front casing 14 and the rear casing 15 may be engaged with each other using, for example, latches provided to the front casing 14 and the rear casing 15. The latches may include a hook shape, a claw shape, or the like. After engagement of the rear casing 15, the front casing 14 and the rear casing 15 are fixed to each other with a fastening member such as a screw. In this way, the upper housing 11 is assembled. In a state in which the upper housing 11 is assembled, the first bumper 16 partially covers the side faces of the upper housing 11. For example, the first bumper 16 partially covers the side faces of the upper housing 11 at the end portion of the upper housing 11 opposite to the hinge 13. The assembly of the upper housing 11 is not limited to the example described above but may include any appropriate steps.

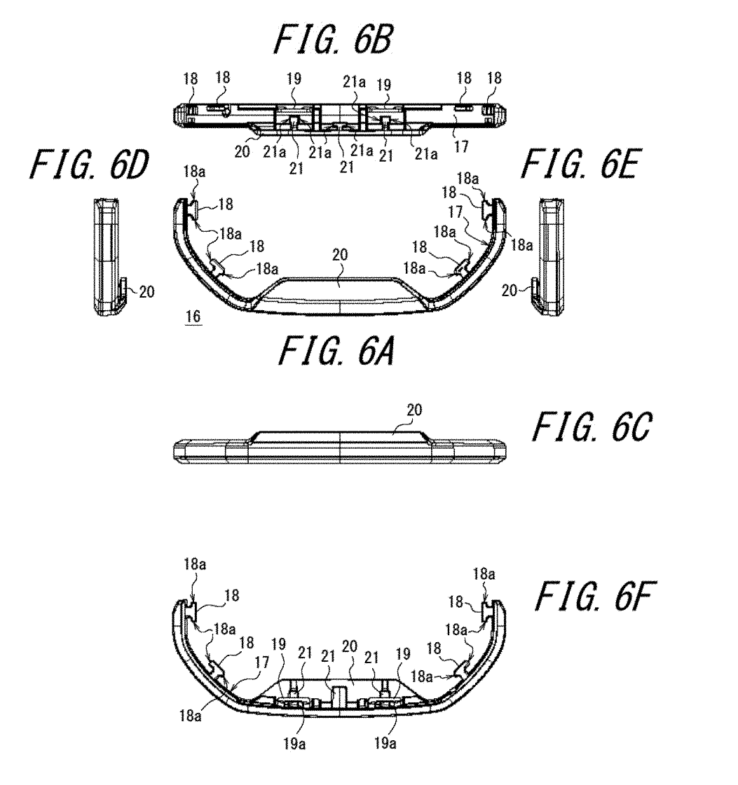

The first bumper 16 will be described in detail with reference to FIGS. 6A to 6F. FIG. 6A is a front view of the first bumper 16. FIG. 6B is a plan view of the first bumper 16. FIG. 6C is a bottom view of the first bumper 16. FIG. 6D is a left-side view of the first bumper 16. FIG. 6E is a right-side view of the first bumper 16. FIG. 6F is a rear view of the first bumper 16.

The first bumper 16 is, for example, substantially C-shaped. An inner peripheral surface 17 of the C-shape faces the side faces of the upper housing 11. Hereinafter, the inner peripheral surface 17 of the first bumper 16 is also referred to as a core-side face of the first bumper 16. An outer peripheral surface of the C-shape partially forms an exterior of the electronic device 10. Hereinafter, the outer peripheral surface of the first bumper 16 is also referred to as a cavity-side face of the first bumper 16. For example, the inner peripheral surface 17 and the outer peripheral surface of the first bumper 16 may each include at least one flat surface and at least one curved surface. The inner peripheral surface 17 of the first bumper 16 may have a shape to contact the side faces of the upper housing 11. The first bumper 16 includes a first latch 18, a second latch 19, and an ear portion 20 that protrude from the inner peripheral surface 17. Any number of the first latch 18, the second latch 19, and the ear portion 20 of the first bumper 16 may be provided. In the example illustrated in FIGS. 6A to 6F, the first bumper 16 includes four first latches 18, two second latches 19, and one ear portion 20.

The first latch 18 includes, for example, a distal end portion that protrudes from the inner peripheral surface 17 in an engaging shape for engagement with the upper housing 11. The engaging shape may include, for example, a hook shape 18a. The first latch 18 including the hook shape 18a is engaged with a side wall of the upper housing 11 from the inside of the upper housing 11, as described later. Being engaged with the side wall of the upper housing 11, the first latch 18 is prevented from separating from the upper housing 11. For example, the four first latches 18 may be provided spaced apart from one another along the circumferential direction of the inner peripheral surface 17. For example, two first latches 18 may be provided in the vicinity of either end of the circumferential direction of the inner peripheral surface 17.

The second latch 19 has, for example, a plate-like shape that protrudes from the inner peripheral surface 17. For example, a direction parallel to a surface of the plate-like shape of the second latch 19 may substantially coincide with the circumferential direction of the inner peripheral surface 17. A distal end portion of the second latch 19 is inserted into a groove formed on a side face of the front casing 14, as described later. The second latch 19 includes, for example, a proximal end portion that protrudes from the inner peripheral surface 17 in an engaging shape for engagement with the upper housing 11. The engaging shape may include, for example, a through hole 19a. A projection 15a that protrudes from a face of the rear casing 15 facing the front casing 14 as illustrated in FIG. 5 is inserted into the through hole 19a of the second latch 19. The second latch 19 is engaged with the projection 15a of the rear casing 15 inserted into the through hole 19a. When being engaged with the projection 15a of the rear casing 15, the second latch 19 is prevented from separating from the upper housing 11. For example, two second latches 19 may be provided spaced apart from each other along the circumferential direction of the inner peripheral surface 17. For example, two second latches 19 may be provided in the vicinity of the center of the circumferential direction of the inner peripheral surface 17.

The ear portion 20 has, for example, a plate-like shape that at least partially protrudes from the circumferential direction of the inner peripheral surface 17. For example, a direction parallel to a surface of the plate-like shape of the ear portion 20 may substantially coincide with the circumferential direction of the inner peripheral surface 17. The ear portion 20 may protrude from the center of the circumferential direction of the inner peripheral surface 17. One of the faces of the plate-like shape of the ear portion 20 partially forms the exterior of the electronic device 10. Hereinafter, this face of the ear portion 20 is also referred to as a cavity-side face of the ear portion 20. The other face of the plate-like shape of the ear portion 20 is facing a second face of the front casing 14 opposite to a first face of the front casing 14 that is facing the rear casing 15, as described later. Hereinafter, the other face of the plate-like shape of the ear portion 20 is also referred to as a core-side face of the ear portion 20.

The ear portion 20 includes a third latch 21 that protrudes from a rear-side surface thereof. The third latch 21 may include, for example, a distal end portion that protrudes from the rear-side surface of the ear portion 20 in an engaging shape for engagement with the front casing 14. The engaging shape may include, for example, a hook shape 21a. The third latch 21 having the hook shape 21a is engaged with a fourth latch provided on the second face of the front casing 14, as described later. Being engaged with the fourth latch of the front casing 14, the ear portion 20 is prevented from coming loose from the front casing 14. Although in the example illustrated in FIGS. 6A to 6F the third latch 21 extends to the inner peripheral surface 17, the third latch 21 may be spaced apart from the inner peripheral surface 17.

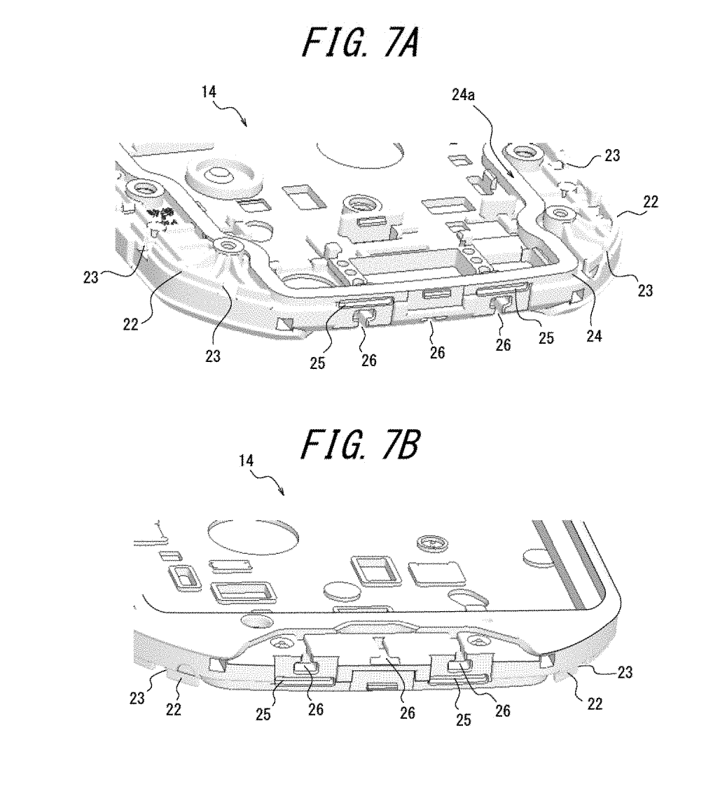

The front casing 14 will be described in detail with reference to FIGS. 7A and 7B. FIG. 7A illustrates an end portion of the first face of the front casing 14, and this first face is facing the rear casing 15. Hereinafter, the first face of the front casing 14 is also referred to as a core-side face of the front casing 14. FIG. 7B illustrates an end portion of the second face of the front casing 14, and the second face is opposite to the first face. Hereinafter, the second face of the front casing 14 is also referred to as a cavity-side face of the front casing 14.

As illustrated in FIG. 7A, the front casing 14 includes a cutout 23 formed on a part of a side wall 22 that protrudes from the core-side face of the front casing 14. The side wall 22 of the front casing 14 may, for example, at least partially form the side wall of the upper housing 11. The cutout 23 is formed to accommodate the first latch 18 of the first bumper 16 as described above. In an example illustrated in FIG. 7A, four cutouts 23 are formed to respectively accommodate the four first latches 18. As will be described later, when the first bumper 16 is temporarily fixed to the front casing 14, proximal end portions of the first latches 18 of the first bumper 16 are respectively accommodated in the cutouts 23 of the front casing 14. In a state in which the upper housing 11 is assembled, the hook shape 18a of the first latch 18 of the first bumper 16 is engaged with the side wall of the upper housing 11 from the inside of the upper housing 11.

The front casing 14 has a first wall 24 that surrounds at least a partial region of its core-side face. The first wall 24 has a shape in conformance with a second wall that surrounds at least a partial region of a face of the rear casing 15 facing the front casing 14. In a state in which the upper housing 11 is assembled, the first wall 24 of the front casing 14 and the second wall of the rear casing 15 are brought into tight contact with each other via a waterproof member. The waterproof member may include, for example, a double-sided tape having waterproofing properties or an elastic member. The waterproof member may be integrally formed with the first wall 24 or the second wall, or may be provided as an individual member. The upper housing 11 has a waterproofed space defined by at least the first wall 24 and the second wall. The substrate having the electronic components mounted thereon and so on are disposed, for example, in the waterproofed space.

The front casing 14 includes one or more grooves 25 on a side face in its end portion thereof. The one or more grooves 25 may be provided to correspond to the number of second latches 19 of the first bumper 16 described above. In the example illustrated in FIGS. 7A and 7B, two grooves 25 are formed in a manner corresponding to the two second latches 19. The grooves 25 extend, in their depth directions, to the first wall 24 positioned in the end portion of the front casing 14. Bottom surfaces of the grooves 25 are positioned between an outer peripheral surface and an inner peripheral surface of the first wall 24. As will be described later, when the first bumper 16 is temporarily fixed to the front casing 14, the distal end portions of the second latches 19 of the first bumper 16 are inserted into the grooves 25 of the front casing 14.

The front casing 14 includes one or more fourth latches 26 on the cavity-side surface in its end portion. The one or more fourth latches 26 may be provided to correspond to number of the third latches 21 of the first bumper 16 described above. In the example illustrated in FIGS. 7A and 7B, three fourth latches 26 are provided in a manner corresponding to the three third latches 21. The fourth latch 26 has a groove shape that extends in a direction, for example, substantially coinciding with the depth direction of the groove 25 from the side face of the end portion of the front casing 14. The groove shape has a cross-section in conformance with the hook shape 21a of the third latch 21 of the first bumper 16. As will be described later, when the first bumper 16 is temporarily fixed to the front casing 14, the third latch 21 of the first bumper 16 is inserted into the fourth latch 26 of the front casing 14.

Referring back to FIG. 5, a process to temporarily fix the first bumper 16 to the front casing 14 will be described. For example, an assembly person inserts the second latches 19 of the first bumper 16 into the grooves 25 of the front casing 14. The assembly person inserts the third latches 21 of the first bumper 16 into the fourth latches 26 of the front casing 14. The assembly person inserts the proximal end portions of the first latches 18 of the first bumper 16 into the cutouts 23 of the front casing 14.

In a state in which the first bumper 16 is temporarily fixed to the front casing 14, the through hole 19a formed in the proximal end portion of the second latch 19 of the first bumper 16 is at least partially exposed when viewed from the core-side face of the front casing 14. The assembly person inserts the protrusions 15a of the rear casing 15 into the through holes 19a to engage the rear casing 15 with the front casing 14. The assembly person fixes the front casing 14 and the rear casing 15 with the fastening member.

In the upper housing 11 assembled in this manner, the first latch 18 of the first bumper 16 passes through the hole formed on the side face of the upper housing 11 and extends to the inside of the upper housing 11. At least some of the holes may include the cutouts 23 of the front casing 14. The first latch 18 is engaged with the side wall of the upper housing 11 from the inside of the upper housing 11. The second latch 19 of the first bumper 16 is engaged with the projection 15a of the rear casing 15, and the projection 15a is inserted into the through hole 19a of the second latch 19. The third latch 21 of the first bumper 16 is engaged with the fourth latch 26 of the front casing 14.

The lower housing 12 may be assembled in the same manner as the upper housing 11 as described above, and the second bumper 27 and the third bumper 28 may be assembled in the same manner as the first bumper 16 as described above. For example, the lower housing 12 may include a front casing and a rear casing, as with the upper housing 11. The second bumper 27 and the third bumper 28 may each be, for example, substantially C-shaped or L-shaped. The second bumper 27 and the third bumper 28 may each be provided with at least one latch having the same configuration as at least one of the first latch 18, the second latch 19, and the third latch 21 described above.

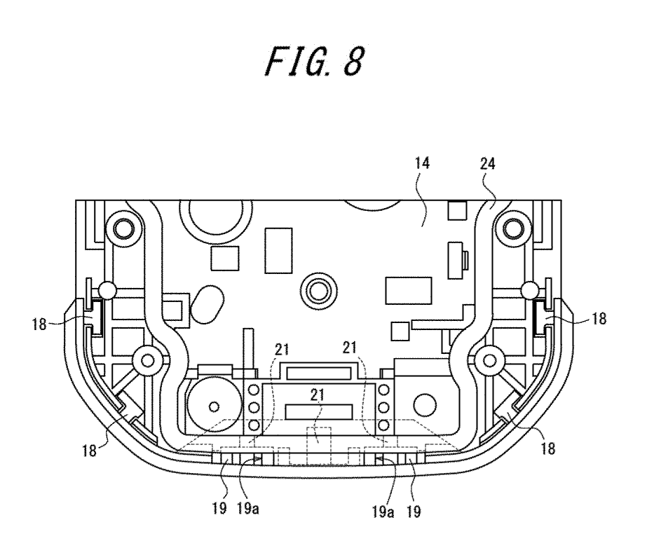

As described above, the electronic device 10 according to the embodiment of the present disclosure includes the upper housing 11 that includes the front casing 14 and the rear casing 15, and the first bumper 16. The first latch 18 of the first bumper 16 extends to the inside of the upper housing 11 and engaged with the side wall of the upper housing 11 from the inside of the upper housing 11. The second latch 19 of the first bumper 16 includes the distal end portion inserted into the groove 25 of the front casing 14 and is engaged with the protrusion 15a of the rear casing 15 inserted into the through hole 19a. As illustrated in FIG. 8 by way of example, for the locking with the first latch 18, a relatively large space is required to accommodate the first latch 18 inside the upper housing 11 excluding the waterproof space. On the other hand, for the locking with the second latch 19, the groove 25 is simply provided on the side face of the front casing 14. Therefore, the locking with the second locking portion 19 requires a relatively small space inside the upper housing 11 outside the waterproof space. According to the electronic device 10, for example, by disposing the second latch 19 in a space that would be too small for the locking with the first latch 18, the first bumper 16 may be fixed to the upper housing 11 in a space-saving manner. Therefore, the electronic device 10 may be prevented from becoming bulky on account of the bumper.

For example, in an electronic device that is required to have waterproof properties, both the downsizing of the electronic device itself and the expansion of the waterproofed space are desired. According to the embodiment of the present disclosure, the grooves 25 necessary for the locking of the second latches 19 of the first bumper 16 may be formed on the first wall 24 that defines the waterproofed space of the electronic device 10. Therefore, when the first wall 24 is provided close to the side face of the upper housing 11, the second latch 19 may be locked in this area. As such, the electronic device 10 according to the embodiment of the present disclosure has a configuration particularly suitable for, for example, an electronic device that is required to have waterproof properties.

In the electronic device 10 according to the embodiment of the present disclosure, as described above, the first bumper 16, the second bumper 27, and the third bumper 28 are provided at the portions that are likely to first hit the ground when the electronic device 10 is dropped. This configuration improves the durability of the electronic device 10 without providing a bumper at portions that are unlikely to first hit the ground. For example, the bumpers do not need cover the entire side faces of the upper housing 11 and the lower housing 12. Therefore, the electronic device 10 is prevented from becoming bulky on account of the bumper.

Although the present disclosure has been described based on the figures and the embodiment, it is to be understood that various modifications and changes may be easily implemented based on the present disclosure by those who are skilled in the art. Accordingly, such modifications and changes are included in the scope of the present disclosure. For example, functions and the like included in each means or step may be rearranged without logical inconsistency, so as to combine a plurality of means or steps together or to separate them.

In the above embodiment, the protrusion 15a is integrally formed with the rear casing 15. However, for example, a member for performing a function similarly to the protrusion 15a may be provided independently of the rear casing 15. Such a member may be, for example, a metal columnar member. In particular, the assembly person, after temporary attaching the first bumper 16 to the front casing 14, may insert this member into the through hole 19a of the second latch 19 of the first bumper 16. One end of this member may be fitted into a hole of the front casing 14, while the other end of this member may be fitted into a hole of the rear casing 15. This configuration, similarly to the above embodiment, prevents the electronic device 10 from becoming bulky on account of the bumper.

In the above embodiment, the electronic device 10 includes one first bumper 16. However, the electronic device 10 may include a plurality of first bumpers. Each of the plurality of first bumpers at least partially covers the end portion of the upper housing 11 on the side facing away from the lower housing 12. For example, two first bumpers may cover the respective corners in the end portion of the upper housing 11 on the side facing away from the lower housing 12.

In the above embodiment, the electronic device 10 includes two second bumpers 27. However, the electronic device 10 may include one or more second bumpers. Each of the one or more second bumpers at least partially covers the end portion of the upper housing 11 on the side facing away from the lower housing 12. For example, one second bumper may cover the two corners in the end portion of the lower housing 12 on the side facing away from the upper housing 11.

In the above embodiment, the electronic device 10 includes two third bumpers 28. However, the electronic device 10 may include one or more third bumpers. Each of the one or more third bumpers at least partially covers the end portion of the upper housing 11 on the side facing the lower housing 12. For example, one third bumper may cover the two corners in the end portion of the lower housing 12 on the side facing the upper housing 11.

In the above embodiment, the window 29 is provided to the upper housing 11 of the electronic device 10. However, the window 29 may be provided to the lower housing 12. For example, a camera module provided inside the lower housing 12 may form an image of the light that has entered the window 29 provided to the lower housing 12.

In the above embodiment, the second bumper 27 and the third bumper 28 may each protrude outward from the rear-side face of the lower housing 12. This configuration prevents the rear-side face of the lower housing 12a from hitting a surface on which the electronic device 10 is to be put with, for example, the rear-side face of the lower housing 12 facing down. Therefore, the durability of the electronic device 10 is further improved.

1. An electronic device comprising:
a housing including a first casing and a second casing engaged with each other, and a bumper which partially covers a side face of the housing, wherein:
the bumper includes a first latch and a second latch that protrude from a surface of the bumper which faces the side face of the housing;
the first latch extends to an inner part of the housing through a hole formed on the side face of the housing and engages a side wall of the housing from inside of the housing; and
the second latch includes a through hole, is inserted into a groove formed on the side face of the first casing, and engages a protrusion that protrudes from a face of the second casing facing the first casing and is inserted into the through hole.

2. The electronic device according to claim 1, wherein:
the first casing includes a first wall surrounding at least a partial region of a face of the first casing facing the second casing;
the second casing includes a second wall surrounding at least a partial region of a face of the second casing facing the first casing and having a shape in conformance with the first wall;
the housing has a waterproofed space defined by the first wall and the second wall; and
the groove formed on the side face of the first casing extends to the first wall in a depth direction.

3. The electronic device according to claim 1, wherein:
the bumper includes an ear portion that at least partially covers a second face of the first casing opposite to a first face of the first casing that faces the second casing;
the ear portion includes a third latch which protrudes from a face of the bumper facing the second face of the first casing; and
the third latch engages a fourth latch provided on the second face of the first casing.

4. The electronic device according to claim 2, wherein:
the bumper includes an ear portion that at least partially covers a second face of the first casing opposite to a first face of the first casing that is facing the second casing;
the ear portion includes a third latch which protrudes from a face of the bumper facing the second face of the first casing; and
the third latch engages a fourth latch provided on the second face of the first casing.

5. An electronic device comprising:
a first housing and a second housing which are openably and closably coupled to each other via a hinge;
at least one first bumper which at least partially covers a second end portion of the first housing opposite to a first end portion of the first housing connected to the second housing via the hinge;
at least one second bumper which at least partially covers a fourth end portion of the second housing opposite to a third end portion of the second housing connected to the first housing via the hinge; and
at least one third bumper which at least partially covers the third end portion of the second housing.

6. The electronic device according to claim 5, wherein
the at least one first bumper covers corners in the second end portion of the first housing;
the at least one second bumper covers corners in the fourth end portion of the second housing; and
the at least one third bumper covers corners in the third end portion of the second housing.

7. The electronic device according to claim 5, wherein:
when the first housing and the second housing are in a closed state, the at least one third bumper protrudes outward from the first housing in a direction of a rotational axis of the hinge.

8. The electronic device according to claim 6, wherein:
when the first housing and the second housing are in a closed state, the at least one third bumper protrudes outward from the first housing in a direction of a rotational axis of the hinge.

9. The electronic device according to claim 5, further comprising:
a window, at least one bezel portion, and at least one fourth bumper on a second face of one of the first housing and the second housing which is opposite to a first face of the one of the first housing and the second housing, the first face facing the other of the first housing and the second housing, wherein:
the at least one bezel portion partially surrounds a periphery of the window; and
the at least one fourth bumper partially surrounds the periphery of the window and protrudes outward from the second face further than the window and the at least one bezel portion.

10. The electronic device according to claim 6, further comprising
a window, at least one bezel portion, and at least one fourth bumper on a second face of one of the first housing and the second housing which is opposite to a first face of the one of the first housing and the second housing, the first face facing the other of the first housing and the second housing, wherein:
the at least one bezel portion partially surrounds a periphery of the window; and
the at least one fourth bumper partially surrounds the periphery of the window and protrudes outward from the second face further than the window and the at least one bezel portion.

11. The electronic device according to claim 7, further comprising:
a window, at least one bezel portion, and at least one fourth bumper on a second face of one of the first housing and the second housing which is opposite to a first face of the one of the first housing and the second housing, the first face facing the other of the first housing and the second housing, wherein:
the at least one bezel portion partially surrounds a periphery of the window; and
the at least one fourth bumper partially surrounds the periphery of the window and protrudes outward from the second face further than the window and the at least one bezel portion.

12. The electronic device according to claim 8, further comprising:
a window, at least one bezel portion, and at least one fourth bumper on a second face of one of the first housing and the second housing which is opposite to a first face of the one of the first housing and the second housing, the first face facing the other of the first housing and the second housing, wherein:
the at least one bezel portion partially surrounds a periphery of the window, and
the at least one fourth bumper partially surrounds the periphery of the window and protrudes outward from the second face further than the window and the at least one bezel portion.
